(19) United States
(12) Patent Application Publication
(10) Pub. No.: US 2012/0138904 A1
(43) Pub. Date: Jun. 7, 2012

(54) ORGANIC ELECTROLUMINESCENCE DISPLAY AND PRODUCTION METHOD THEREOF

(76) Inventors: Takahisa Shimizu, Minamisaitama-gun (JP); Koji Takeshita, Kawagos-shi (JP); Hironori Kawakami, Tokyo (JP); Nahoko Inokuchi, Soka-shi (JP)

(21) Appl. No.: 12/733,748

(22) PCT Filed: Sep. 19, 2008
(86) PCT No.: PCT/JP2008/066974

§ 371 Date: Aug. 6, 2010

(30) Foreign Application Priority Data
Sep. 21, 2007 (JP) 2007 245804

(51) Int. Cl. H01L 27/32; H01L 51/56

(52) U.S. Cl. 257/40; 438/35; 257/E27.119; 257/E51.022

(57) ABSTRACT

An organic electroluminescence display includes a substrate, a first electrode layer formed on the substrate, a first light emitting layer formed on the first electrode layer and emitting light with a first wavelength, a second light emitting layer formed to overlap at least a part thereof with the first light emitting layer and emitting light with a second wavelength longer than the first wavelength, and a second electrode layer formed on the first or second light emitting layer.

### TECHNICAL FIELD

The present invention relates to an organic electroluminescence display and a production method thereof.

Priority is claimed on Japanese Patent Application No. 2007-245804, filed Sep. 21, 2007, the content of which is incorporated herein by reference.

### BACKGROUND ART

Generally, in organic EL (Electro Luminescence) elements, an organic light emitting medium layer made of an organic light emitting material is formed between two opposite electrode substrates, and light is emitted by allowing electric current to flow into the organic light emitting medium layer. To emit light with high efficiency, it is important to control the thickness of the organic light emitting medium layer, which has to be extremely thin, for example, about 100 nm. In addition, to make it into a display, it is necessary to perform patterning with high precision.

As organic light emitting materials formed on substrates or the like, there are low molecular materials and high molecular materials. Generally, the low molecular material is formed into a thin film on a substrate by a resistance heating deposition method (vacuum deposition method) or the like, and patterning is performed using a micro pattern mask at that time. However, in this method, there is a problem that it is difficult to achieve precision in patterning as the substrate gets larger.

Recently, a method has been tried using a high molecular material as an organic light emitting material formed on a substrate or the like, in which the organic light emitting material made into an ink by dissolving in a solvent, is formed into a coating ink liquid, and then is formed into a thin film by a wet coating method. As a wet coating method for forming thin films, there is a spin coat method, a bar coat method, a protrusion coat method, a dip coat method, and the like. However, it is difficult to perform patterning with high precision or to separately coat three colors of red (R), green (G), and blue (B) by such wet coating methods, and it is considered that it is most effective to form a thin film by pattern printing in a printing method characterized by patterning of separate coating.

Among various kinds of printing methods, there are many cases of using a glass substrate as a substrate in an organic EL element or a display, and thus a method such as a gravure printing method using a hard plate such as a metal printing plate is not appropriate. For this reason, a printing method using a printing board made of rubber having elasticity, an offset printing method using a printing blanket made of rubber, a convex board printing method using a photosensitive resin board made of rubber having elasticity or the other resin as a main component, and the like can be employed as a proper printing method. Actually, as an attempt of such a printing method, a pattern printing method (Patent Document 1) based on offset printing, a pattern printing method (Patent Documents 2 and 3) based on convex board printing, and the like have been proposed.

Although not shown, as a circular-pressing convex board offset printing machine, there is a printing machine based on a cylindrical rotating blanket body and a flat press platen fixed to a fixed position. The printing machine is provided with a flat plate fixing platen for horizontally placing, positioning, and fixing a flat convex printing board, a flat printing target fixing platen (press platen) for horizontally placing, positioning, and fixing a printing target (printing board), an ink feed roller that moves (rolling) in circumferential contact with the surface of the convex printing board placed and fixed onto the plate fixing platen to adhere ink to the top face, and a blanket body that moves (rolling) in circumferential contact with the surface of the convex printing board at the waiting time of the ink feed roller to transfer the ink adhered to the top face to a blanket face with a rubber surface and further rolls to transfer the ink transferred to the blanket face to the printing target (printing board) placed and fixed onto the printing target fixing platen, thereby performing printing.

Meanwhile, in the convex board printing method, it has been known that a viscous (thixotropic) ink for coating or a liquefied ink (ink liquid) has optimal viscosity and surface tension, and particularly, a viscosity adjusting agent called a viscosity agent, a surfactant for adjusting surface tension, and the like are generally added to a liquefied ink.

In case of printing an electronic material, there is a limit to the solubility thereof or there is a case of disliking impurities. Accordingly, there is a case where the limit of the physical properties of ink is large.

Particularly, when an organic light emitting material is printed by the printing method to form a film, the organic light emitting material is dispersed or dissolved in a solvent (binder resin as necessary) such as water, alcohol, or organic solvent, and thus becomes a printing or coating ink liquid.

When the organic light emitting material is subjected to patterning and formed into a film and is driven as an element, it is considered that durability of the element is good in a case where purity of the film formed by the organic light emitting material is high. Accordingly, since a viscosity agent or the like remaining in the film of the organic light emitting material the causes purity to decrease, a viscosity agent cannot be added. For this reason, the adjustable range of various physical properties of the organic light emitting material ink liquid to obtain an ink transfer property of a printing object and stability of a pattern shape is limited.

From the above-described reason and the low solubility, particularly in the case of the light emitting material, only some aromatic solvents can be used and the selection range of ink is not so wide.

Patent Document 1: Japanese Patent Application, First Publication No. 2001-93668

Patent Document 2: Japanese Patent Application, First Publication No. 2001-155858

Patent Document 3: Japanese Patent Application, First Publication No. 2001-155861

### DISCLOSURE OF INVENTION

### Problem to be Solved by the Invention

A mobile display panel such as a mobile phone, a PDA (Personal Digital Assistant: mobile information terminal), or a digital camera needs a high-precision display of 100 ppi or more. However, in such high-precision displays, the distance between pixels becomes narrow, for example, about 40 to 10 μm. Accordingly, when the positional precision of printing is low, the printing pattern is out of alignment and crowds the vicinity of adjacent pixels and solidifies. Even when the positional precision is not low and when the liquid printing ink comes close to the vicinity of the printing pattern of the adjacent pixels, the solidified printing pattern is dissolved again in the approaching printing ink and is dissolved in the printing ink, thereby occasionally causing a problems with mixing of colors.

Particularly, when a material (substantially, long (red)>(green)>(blue) short) with a long light emitting wavelength is mixed into a material with a short wavelength, the material with the long wavelength preferentially emits light by a phenomenon of energy movement in the organic EL. That is, when red with a long wavelength is mixed into blue with a short wavelength, the color of the light emitted deviates significantly from blue and light emitted becomes close to white.

An object of the present invention is to provide an organic electroluminescence display and a production method thereof capable of lowering differences in chromaticity caused by mixed colors of ink to the minimum and improving production yield.

### Means for Solving the Problem

(1) The invention has been made to solve the above-described problems, and an organic luminescence display according to an aspect of the present invention includes a substrate, a first electrode layer that is formed on the substrate, a first light emitting layer that is formed on the first electrode layer and emits light with a first wavelength, a second light emitting layer that is formed to overlap at least a part thereof with the first light emitting layer and emits light with a second wavelength longer than the first wavelength, and a second electrode layer that is formed on the first or second light emitting layer.

In the invention, the second light emitting layer emitting light with the second wavelength which is longer than the first wavelength overlaps the first light emitting layer emitting light with the first wavelength. Accordingly, even when pigment included in the first light emitting layer flows into the second light emitting layer, the pigment of the second light emitting layer with energy lower than that of the pigment of the first light emitting layer can preferentially emit light and thus it is possible to prevent a mixed color from occurring.

(2) The organic electroluminescence display of the present invention includes a partition wall formed between adjacent organic electroluminescence elements on the substrate, and the second light emitting layer overlaps with the first light emitting layer on the partition wall.

In the invention, when the first or second light emitting layer is formed, even when a pigment of the first light emitting layer or a pigment of the second light emitting layer does not flow into the partition wall and the pigment goes up on the partition wall, it is possible to prevent a mixed color from occurring.

(3) The first light emitting layer of the organic electroluminescence display of the present invention is formed on all of the faces of the first electrode and the partition wall.

In the invention, it is possible to insulate the first electrode layer and the second electrode layer from each other at the first light emitting layer, and thus it is possible to prevent electric current from leaking between the first electrode layer and the second electrode layer.

The organic electroluminescence display of the present invention includes a hole transport layer between the first electrode layer and the second electrode layer, and the hole transport layer is formed on all of the faces of the first electrode and the partition wall.

In the invention, since the hole transport layer is formed on all of the faces of the first electrode and the partition wall, wetability of the surface in the partition wall can be made uniform and thus the thickness of the first light emitting layer formed right thereon can be made uniform.

(5) A method of producing an organic electroluminescence display of the present invention includes a first process of forming a first electrode layer on a substrate, a second process of forming a first light emitting layer that emits light with a first wavelength on the first electrode layer, a third process of forming a second light emitting layer that emits light with a second wavelength longer than the first wavelength to overlap at least a part thereof with the first light emitting layer, and a fourth process of forming a second electrode layer on the first or second light emitting layer.

In the invention, the second light emitting layer emitting light with the second wavelength longer than the first wavelength is formed to overlap with the first light emitting layer after the first light emitting layer emitting light with the first wavelength is formed. Accordingly, even when a pigment included in the first light emitting layer flows into the second light emitting layer, a pigment of the second light emitting layer with energy lower than that of the pigment of the first light emitting layer can preferentially emit light and thus it is possible to prevent a mixed color from occurring.

(6) In the second process of the method of producing the organic electroluminescence display, the first light emitting layer is formed by patterning ink including a first pigment emitting light with the first wavelength, and in the third process the second light emitting layer is formed by patterning ink including a second pigment emitting light with the second wavelength after the first light emitting layer is solidified.

In the invention, the first light emitting layer is subjected to patterning, the first light emitting layer is solidified and dried, and then the second light emitting layer is subjected to patterning. Accordingly, it is possible to reduce the amount of the first pigment flowing into the second light emitting layer, and thus it is possible to prevent a mixed color from occurring.

(7) In the method of producing the organic electroluminescence display of the present invention, the first or second light emitting layer is formed by a convex board printing method.

(8) The method of producing the organic electroluminescence display of the present invention further includes a process of forming a partition wall for partitioning adjacent organic electroluminescence elements from each other, and in the second process the first light emitting layer is formed on the first electrode layer and the partition wall.

In the invention, when the first or second light emitting layer is formed, even when a pigment of the first light emitting layer or a pigment of the second light emitting layer does not flow into the partition wall and the pigment goes up on the partition wall, it is possible to prevent a mixed color from occurring. Therefore, it is not necessary to perform precise positioning at the time of forming the first light emitting layer or the second light emitting layer. Thus, it is possible to easily produce the organic luminescence display.

### Effect of the Invention

The organic electroluminescence display and the production method thereof of the present invention can suppress differences in chromaticity caused by a mixed color of ink to the minimum and improve production yield.

### BRIEF DESCRIPTION OF THE DRAWINGS

FIG. 1 is a side cross-sectional view illustrating a convex printing board for producing an organic EL display according to an embodiment of the present invention.

FIG. 2 is a schematic view illustrating a configuration of a producing device for the organic EL display according to the embodiment of the present invention.

FIG. 3 is a cross-sectional view illustrating a structure of an organic EL display 100a according to the embodiment of the present invention.

FIG. 4 is a cross-sectional view illustrating a structure of an organic EL display 100b according to a modified example of the embodiment of the present invention.

FIG. 5 is a cross-sectional view illustrating a structure of an organic EL display 100c according to another modified example of the embodiment of the present invention.

FIG. 6 is a view illustrating a method of producing the organic EL display 100b (FIG. 4) according to the modified example of the embodiment of the present invention.

FIG. 7 is a view illustrating the method of producing the organic EL display 100b (FIG. 4) according to the modified example of the embodiment of the present invention.

FIG. 8 is a view illustrating another example of the method of producing the organic EL display 100b (FIG. 4) according to the modified example of the embodiment of the present invention.

FIG. 9 is a view illustrating another example of the method of producing the organic EL display 100b (FIG. 4) according to the modified example of the embodiment of the present invention.

FIG. 10 is a plan view illustrating a structure of the organic EL display 100a (FIG. 3) according to the embodiment of the present invention.

FIG. 11 is a plan view illustrating another example of the structure of the organic EL display 100a (FIG. 3) according to the embodiment of the present invention.

FIG. 12 is a light emitting photograph of an organic EL display produced by Examples 1 and 2 of the present invention.

FIG. 13 is a light emitting photograph of an organic EL display produced by Comparative Example 1.

FIG. 14 is a view illustrating a cause of generating a mixed color in the organic EL display produced by Comparative Example 1.

FIG. 15 is a view illustrating a cause of generating a mixed color in the organic EL display produced by Comparative Example 1.

### REFERENCE SYMBOLS

1a: BASE MATERIAL LAYER OF CONVEX BOARD, 1b: CONVEX PORTION FORMING MATERIAL LAYER, 2: INK TANK, 3: INK EJECTING PORTION, 4a: INK, 5: ANILOX ROLL, 6: BLOCK BODY, 7: PRINTING TARGET, 8: PRINTING TARGET FIXING PLATEN, 9: DOCTOR, 10: SUBSTRATE, 11a, 11b, 11c, 11d: PARTITION WALL, 12a, 12b, 12c: ANODE, 13a, 13b, 13c, 13d, 13e: HOLE TRANSPORT LAYER, 14R, 14G 14B: LIGHT EMITTING LAYER, 15: CATHODE, 16: SEALING RESIN, 17: SEALING SUBSTRATE, 100a, 100b, 100c: ORGANIC EL DISPLAY, S: CONVEX PRINTING BOARD

### BEST MODE FOR CARRYING OUT THE INVENTION

Hereinafter, embodiments of the present invention will be described with reference to the drawings. The invention is not limited thereto.

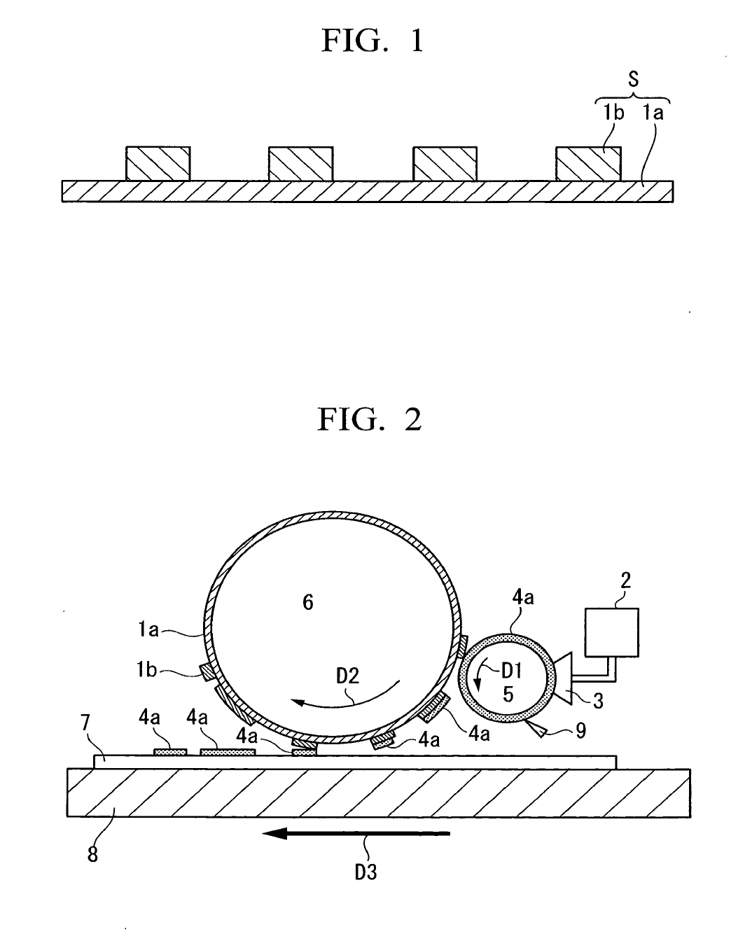

FIG. 1 is a side cross-sectional view of a convex printing board for producing an organic EL display according to an embodiment of the present invention. In FIG. 1, reference numeral 1a denotes a base material layer of the convex board, and reference numeral 1b denotes a convex portion forming material layer (also, referred to as convex portion) on the base material layer 1a. A convex board S is formed by the base material layer 1a and the convex portion forming material layer 1b.

As the convex portion forming material layer 1b, rubber such as nitrile rubber, silicon rubber, isoprene rubber, styrene butadiene rubber, butadiene rubber, chloroprene rubber, butyl rubber, acrylonitrile rubber, ethylene propylene rubber, and urethane rubber, synthetic resin such as polyethylene, polystyrene, polybutadiene, polyvinyl chloride, polyvinylidene chloride, polyvinyl acetate, polyamide, polyether sulfone, polyethylene terephthalate, polyethylene naphthalate, polyether sulfone, polyvinyl alcohol, copolymer thereof, and a natural high molecule such as cellulous can be used.

Among them, a material including a water-soluble polymer as a main component has high resistance to an organic solvent constituting a solution or dispersion liquid of an organic light emitting material that is a component of coating ink, and thus it is preferable to use the material.

For example, when the boiling point of the coating ink of the organic light emitting material that is one of electronic materials gets lower, there is an advantage that the drying process gets easier. However, when a solvent with too low a boiling point is used, ink is dried on the upside of the board. For this reason, it is preferable to prevent ink from drying by appropriately mixing ink with a solvent that has a boiling point of 130° C. or higher.

As a solvent with a boiling point of 130° C. or higher, for example, one or more is selected from 2,3-dimethyl anisole, 2,5-dimethyl anisole, 2,6-dimethyl anisole, trimethyl anisole, tetralin, benzonic acid methyl, benzonic acid ethyl, cychlohexyl benzene, n-amyl benzene, tert-amyl benzene, diphenyl ether, dimetyl sulfoxide, and the like.

As the organic light emitting material, one formed by dissolving a low molecular luminescent pigment in a high molecule such as polystyrene, polymethyl methacrylate, and polyvinyl carbazole, or a high molecular light emitting element such as polyphenylene vinylene derivative (PPV) and polyalkyl fluorene derivative (PAF) is used. Such a high molecular organic light emitting material (light emitting material for high molecular EL element) can be dissolved in a solvent or stably dispersed, and thus a film can be produced by an applying method or a printing method by making it into ink. Accordingly, the film can be produced under atmospheric pressure and has the advantage of a low equipment cost, when compared with the production of an organic EL element using a low molecular light emitting material.

As the convex board S, the above-described material can be used, but also a commercially available flexo board or a resin convex board can be used.

The convex printing board of the embodiment can be provided in a printing machine based on a convex board printing method (printing machine performing printing using a convex printing board) to perform printing, for example, it is provided in a circular-pressing convex board printing machine or a circular-pressing convex board offset printing machine, or the like, to perform printing.

FIG. 2 is a schematic view illustrating a configuration of a producing device for the organic EL display according to the embodiment of the present invention. The production device for the organic EL display shown in FIG. 2 is a circular-pressing convex printing machine using a convex board printing method, and is provided with, as shown, an ink tank 2, an ink ejecting portion 3 (chamber) that is an ink feed portion, an anilox roll 5 (hard roll made of metal or resin, or hard roll with proper elasticity) rotating in an arrow direction D1 (counterclockwise rotating direction about rotating axis perpendicular to paper), and a block body 6 capable of being provided with the convex printing board S (see FIG. 1) and rotating in an arrow direction D2 (clockwise rotating direction about rotating axis perpendicular to paper). The convex printing board includes the base material layer 1a and the convex portion forming material layer 1b. A printing target fixing platen 8 repeatedly moving in a horizontal direction D3 (arrow direction) is provided under the block body 6, and a printing target 7 is placed and fixed onto the platen 8.

The ink tank 2 accommodates ink including a red light emitting pigment, ink including a greed light emitting pigment, and ink including a blue light emitting pigment. Ink including the light emitting pigments of various colors is individually transported from the ink tank 2 to the ink ejecting portion 3 without mixing. The anilox roll 5 is close to the ink ejecting portion 4 and rotates in contact with the convex printing board of the block body 6.

Ink 4a ejected from the ink ejecting portion 3 to a circumferential face of the anilox roll 5 by the rotation of the anilox roll 5 is scraped by a doctor 9 or the like to be a uniform thickness, and is transferred to the circumferential face of the anilox roll 5 as a film of the ink 4a with the uniform thickness. Then, the ink 4a on the circumferential face of the anilox roll 5 is transferred with a uniform thickness to a top face of the convex portion 1b of the convex printing board S provided on the block body 6.

The printing target 7 (printing board) on the printing target fixing platen 8 is horizontally moved to the printing start position in the left direction of the figure as shown in FIG. 2, while adjusting a phase position by a position adjusting mechanism for adjusting a phase position of the printing target 7 and the convex portion pattern formed by the convex portion 1b of the convex printing board.

Then, the printing target fixing platen 8 is horizontally moved in the left direction of the figure according to the rotating speed of the block body 6, while bring the convex portion 1b of the convex printing board S of the block body 6 into contact with the surface of the printing target 7 with a predetermined printing pressure. The convex portion pattern is printed on the surface of the printing target 7 by the ink on the top face of the convex portion S of the convex printing board.

After the printing, the printing target 7 is removed from the upside of the printing target fixing platen 8, and then the next printing target 7 is placed and fixed onto the printing target fixing platen 8. This operation is repeated to perform printing.

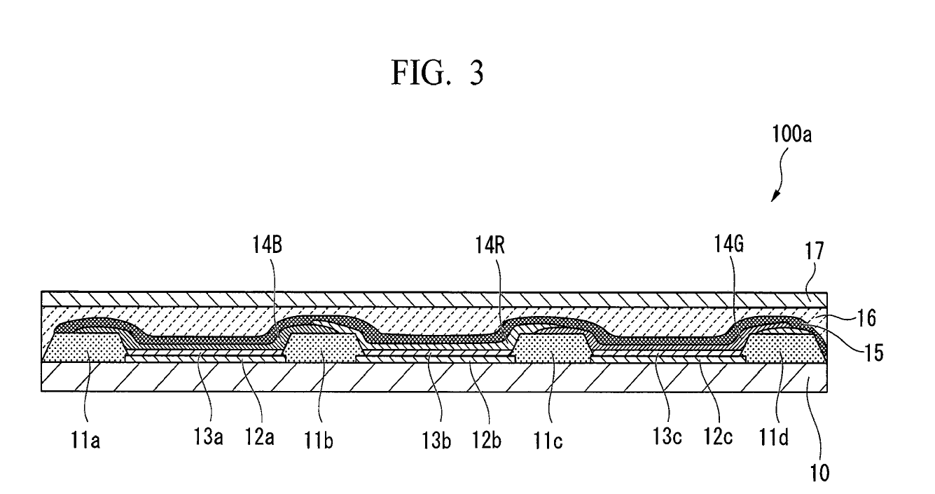

FIG. 3 is a cross-sectional view illustrating a structure of an organic EL display 100a according to the embodiment of the present invention. Trapezoid partition walls 11a, 11b, 11c, and 11d are formed at predetermined intervals on a substrate 10. The substrate 10 may include a TFT (Thin Film Transistor).

On the substrate 10, anodes 12a, 12b, and 12c are formed in a layer shape between the partition wall 11a and the partition wall 11b, between the partition wall 11b and the partition wall 11c, and between the partition wall 11c and the partition wall 11d.

Hole transport layers 13a, 13b, and 13c are formed in a layer shape on the anode 12a, 12b, and 12c.

A light emitting layer 14B is formed on the partition walls 11a and 11b and the hole transport layer 13a by applying ink including an organic light emitting material containing a pigment emitting blue light. A light emitting layer 14G is formed on the partition walls 11c and 11d and the hole transport layer 13c by applying ink including an organic light emitting material containing a pigment emitting green light. A light emitting layer 14R is formed on the partition walls 11b and 11c and the hole transport layer 13b by applying ink including an organic light emitting material containing a pigment emitting red light.

Meanwhile, ink is applied onto the partition walls 11a and 11b and the hole transport layer 13a in order of blue, green and red. For this reason, the light emitting layer 14R weights the light emitting layer 14B on the partition wall 11b. The light emitting layer 14R weights the light emitting layer 14G on the partition wall 11c. The light emitting layer 14G weights the light emitting layer 14B on the partition wall 11d.

A cathode 15 as an opposite electrode is formed in a layer shape on the light emitting layers 14B, 14G, and 14R. A layer of sealing resin 16 is formed on the cathode 15.

A sealing substrate 17 is provided on the sealing resin 16.

In the organic EL display 100a shown in FIG. 3, an area interposed between the partition wall 11a and the partition wall 11b, an area interposed between the partition wall 11b and the partition wall 11c, and an area interposed between the partition wall 11c and the partition wall 11d are organic EL elements.

Next, a method of producing the organic EL display 100a according to the embodiment will be described.

First, a substrate 10 is prepared, and trapezoid partition walls 11a, 11b, 11c, and 11d are formed at predetermined intervals on the substrate 10 between adjacent organic EL elements.

A layer (also referred to as first electrode layer) of anodes 12a, 12b, and 12c are formed at areas among the partition walls 11a, 11b, 11c, and 11d, and hole transport layers 13a, 13b, and 13c are formed on the anodes 12a, 12b, and 12c, respectively.

Ink 4a including a pigment emitting blue light is applied to the areas on the partition wall 11a and the partition wall 11b, and the area between the partition wall 11a and the partition wall 11b to perform patterning, thereby forming a light emitting layer 14B.

The ink 4a including the pigment emitting the blue light is solidified and dried, and then ink 4a including a pigment emitting green light with a light emitting wavelength longer than that of a blue color is applied to the areas on the partition wall 11c and the partition wall 11d and the area between the partition wall 11c and the partition wall 11d so as to overlap at least a part thereof with the light emitting layer 14B to perform patterning, thereby forming a light emitting layer 14G.

The ink 4a including the pigment emitting the green light is solidified and dried, and then ink 4a including a pigment emitting red light with a light emitting wavelength longer than that of a green color is applied to the areas on the partition wall 11b and the partition wall 11c and the area between the partition wall 11b and the partition wall 11c so as to overlap at least a part thereof with the light emitting layer 14B and the light emitting layer 14G to perform patterning, thereby forming a light emitting layer 14R.

The ink 4a including the pigment emitting the red light is solidified and dried, and then a layer (also referred to as second electrode layer) of a cathode 15 is formed on the light emitting layers 14R, 14G, and 14B.

A layer of sealing resin 16 is formed on the cathode 15. A sealing substrate 17 is installed on the sealing resin 16.

In FIG. 3, the ink 4a is applied to a part of the areas on the partition walls 11a, 11b, 11c, and 11d, but the ink 4a may be applied to all the faces on the partition walls 11a, 11b, 11c, and 11d. With such a configuration, it is possible to obtain advantages such as the following (A1), (A2), and (A3).

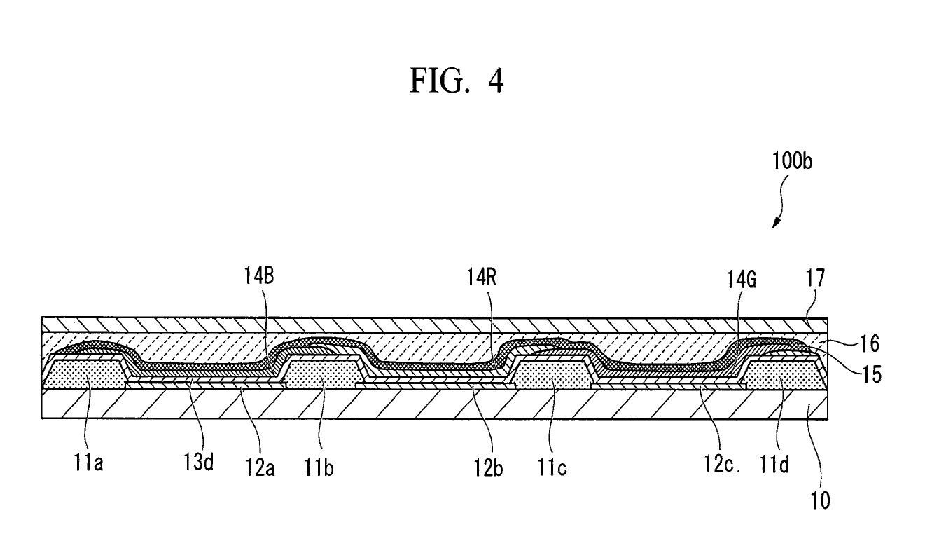

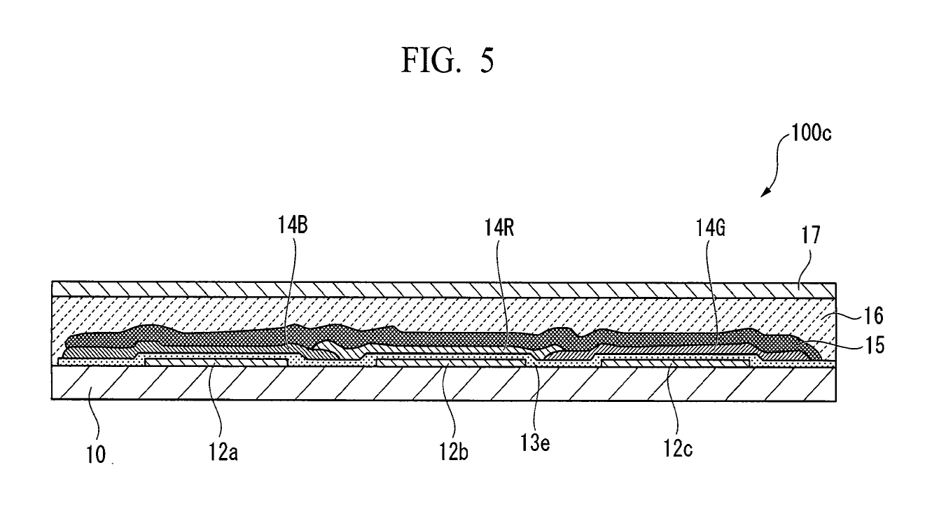

(A1) The light emitting layers 14R, 14G, and 14B have an insulating property, and thus it is possible to block off electric current leaking from the anodes 12a, 12b, and 12c, the cathode 15, or the hole transport layers 13a, 13b, and 13c. Particularly, it is effective in a case where the hole transport layers are also formed on the partition walls on all of the faces of the partition walls 11a, 11b, 11c, and 11d (see FIG. 4 to be described later), and in the case of a passive matrix type without partition walls (see FIG. 5 to be described later).

(A2) When the anodes 12a, 12b, and 12c are formed of resin, gas is generated from the partition walls 12a, 12b, and 12c and may have a negative influence on the organic EL elements. However, all of the faces on the partition walls 11a, 11b, 11c, and 11d are covered with the light emitting layers 14R, 14G, and 14B, and thus it is possible to suppress the problem.

(A3) Wetability of the surfaces of the organic EL elements becomes uniform, it is possible to form a uniform film, and thus it is possible to suppress disconnection. Edges of the partition walls 11a, 11b, 11c, and 11d are covered at the light emitting layer, and it is possible to suppress disconnection of the cathode 15 formed thereon.

The organic EL elements constituting the organic EL display 100a are provided with conductive organic light emitting layers (light emitting layers 14R, 14Q and 14B in FIG. 3), transparent electrode layers (anodes 12a, 12b, and 12c in FIG. 3) disposed on both sides in a thickness direction of the organic light emitting layers, and an opposite electrode layer (cathode 15 in FIG. 3), and the organic EL elements are produced by sequentially laminating and forming the transparent electrode layers, the organic light emitting layers, and the opposite layer on the transparent substrate 10. Voltage is applied to the organic light emitting layers to inject electrons and holes, they are re-coupled, and the organic light emitting layers emit light at the time of the coupling.

Herein, in order to improve the light emitting efficiency of the organic light emitting layers, the hole transport layers 13a, 13b, and 13c are provided between the transparent electrode layers (anodes 11a, 11b, and 11c) and the organic light emitting layers (light emitting layers 14R, 14G, and 14B), but electron transport layers may be provided between the opposite electrode layer (cathode 15) and the organic light emitting layers (light emitting layers 14R, 14G, and 14B).

Next, an organic light emitting medium layer is formed. The organic light emitting medium layer may be independently configured from the organic light emitting layer, and may be configured in a laminated structure of the organic light emitting layer and layers for assisting light emitting such as a hole transport layer, a hole injection layer, an electron transport layer, and an electron injection layer. The hole transport layer, the hole injection layer, the electron transport layer, and the electron injection layer are appropriately selected.

As the light emitting elements used for the organic light emitting layers in the organic EL elements, it is possible to use an element formed by dissolving or copolymerizing a low molecular light emitting pigment such as a coumarin group, a perylene group, a pyrane group, an anthrone group, a porpyrene group, a quinacridone group, an N,N′-dialkyl substituted quinacridone group, a naphthalimide group, an N,N′-diallyl substituted pyrrolo pyrrole group, an iridium complex group, a platinum complex group, and a europium complex group, into a high molecule such as polystyrene, polymethyl methacrylate, and polyvinyl carbazole, or to use a high molecular light emitting element such as a polyarylene group, a polyarylene vinylene group, and a polyfluorene group.

In addition, it is possible to use an element formed by dispersing a low molecular group light emitting material such as a phosphorescent light emitting element such as an Ir complex, for example, a coumarin group fluorescent element, a perylene group fluorescent element, a pyrane group fluorescent element, an anthrone group fluorescent element, a polyphrine group fluorescent element, a quinacridone group fluorescent element, an N,N′-dialkyl substituted quinacridone group fluorescent element, a naphthalimide group fluorescent element, and an N,N′-diallyl substituted pyrrolo pyrrole group fluorescent element, into a high molecule. A high molecular light emitting element such as polystyrene, polymethyl methacrylate, polyvinyl carbazole, and the like can be used as the high molecule. In addition, high molecular light emitting materials such as a polyarylene group, a polyarylene vinylene group, polyfluorene, polyphenylene vinylene, polyparaphenylene vinylene, polythiophene, and polyspiro may be used. A material formed by dispersing or copolymerizing the low molecular material into the high molecular material, or other existing light emitting material may be used.

As a material used for the hole transport layer 13c, a material generally used as the hole transport material may be used, a low molecule such as an aromatic amine group of copper phthalocyanine or a derivative thereof, 1,1-bis(4-di-p-toly amino phenyl)cychlo hexane, N,N′-diphenyl-N,N′-bis(3-methyl phenyl)-1,1′-biphenyl-4,4′-diamine, N,N′-di(1-naphthyl)-N,N′-diphenyl-1,1′-biphenyl-4,4′-diamine, and the like may be used, but a high molecular material such as a compound of a polyaniline derivative, a polythiophene derivative, a polyvinylcarbazole (PVK) derivative, or poly(3,4-ethylenedioxythiophene) and polystyrene sulfonic acid is preferable from the viewpoint of a film forming property. In addition, a material may be used, which is formed by mixing a material representing a charge transport property such as arylamines, carbazole derivatives, arylsulfides, thiophene derivatives, and phthalocyanine derivative of low molecules, into a conductive high molecule such as a polyarylene group such as poly para phenylene (PPP) and a polyarylene vinylene group such as polyphenylene vinylene (PPV), or a high molecule such as polystyrene (PS).

As a material used for the hole transport layer 13c, an inorganic material may be used, and alkali metal elements such as Li, Na, K, Rb, Ce and Fr, alkali earth metal elements such as Mg, Ca, Sr, and Ba, lanthanoid elements such as La, Ce, Pr, Nd, Sm, Eu, Gd, Db, Dy, Ho, Er, Tm, Yb, and Lu, actinoid elements such as Th, metal elements such as Sc, Ti, V, Cr, Fe, Co, Ni, Cu, Zn, Y, Ar, Nb, Mo, Ru, Pd, Ag, Cd, Hf, Ta, W, Re, Os, Ir, Pt, Au, Al, Ga, In, Sn, Ti, Pb, and Bi, semimetal elements such as B, Si, Ge, As, Sb, and Te, and further inorganic compounds such as alloys, oxides, carbides, nitrides, bromides, sulfides, and halides thereof may be used.

Among them, particularly, when using a molybdenum oxide, a film is easily formed, a hole injection function from a hole injection electrode is high, and a function of transporting holes stably is excellent. Accordingly, it is known that the molybdenum oxide is a useful material as a part of a hole transport material and an electron injection material from the viewpoint of stability and the like.

A material adding adhesion to the electron transport layer by heating, which is called an interlayer, may be provided between the organic light emitting layer and the hole transport layer 13c in the organic EL element. It is known that light emitting efficiency of the organic light emitting layer increases and a driving durability extends by the interlayer. As such a material, there is poly(2,7-(9,9-di-octylfluorene))-alt-(1,4-phenylene-((4-sec-butyl phenyl) imino)-1,4-phenylene))(TFB).

When an inorganic material is used as the hole transport material, as the inorganic material, metal oxides such as Cu₂O, Cr₂O₃, Mn₂O₃, FeOₓ (x˜0.1), NiO, CoO, Pr₂O₃, Ag₂O, MoO₂, Bi₂O₃, ZnO, TiO₂, SnO₂, ThO₂, V₂O₅, Nb₂O₅, Ta₂O₅, MoO₃, WO₃, and MnO₂ are formed using a deposition method, a spattering method, or a CVD (Chemical Vapor Deposition) method. However, the materials are not limited thereto. Carbides, nitrides, bromides, and the like of the metals may be used. A film can be formed by a vacuum deposition method, a spattering method, a CVD method, or the like.

As the material of the electron transport layer, 2-(4-biphenylyl)-5-(4-t-butyl phenyl)-1,3,4-oxadiazole, 2,5-bis(1-naphthyl)-1,3,4-oxadiazole, oxadiazole derivatives or bis(10-hydroxybenzo[h]quinolinolate)beryllium complex, triazole compounds, and the like may be used.

Such materials can be used by the spattering method, the CVD method, and the like using the inorganic materials. In the case of low molecule, a film may be formed using the deposition method, but it is used as application liquid by dissolving or dispersing it into independent or mixed solvent such as toluene, xylene, acetone, anisole, methyl anisole, dimethyl anisole, benzonic acid ethyl, benzonic acid methyl, mesitylene, tetralin, amyl benzene, methyl ethyl ketone, methyl isobutyl ketone, cyclohexanone, methanol, ethanol, isopropyl alcohol, ethyl acetate, butyl acetate, and water. In addition, it is possible to form a film using a coating method such as a spin coat method, a curtain coat method, a bar coat method, a wire coat method, a slit coat method, or a printing method such as a convex board printing method (flexography method), a concave board offset printing method, a convex board reverse offset printing method, an inkjet printing method, and a concave board printing method.

In the embodiment, a case where the organic EL display has the structure shown in FIG. 3 has been described, but is not limited to such a structure. For example, the structure of the organic EL display may be as shown in FIG. 4 or FIG. 5.

FIG. 4 is a cross-sectional view illustrating a structure of an organic EL display 100b according to a modified example of the embodiment of the present invention. In FIG. 4, the same reference numerals and signs are given to parts having the same structure as FIG. 3, and the description thereof is not repeated.

The organic EL display 100b shown in FIG. 4 is different from the organic EL display 100a shown in FIG. 3 in that the hole transport layer 13c is formed on the partition walls 11a, 11b, 11c, and 11d as well as on the anodes 12a, 12b, and 12c.

The hole transport layer 13c is formed on the partition walls 11a, 11b, 11c, and 11d, and the anodes 12a, 12b, and 12c, that is, on the whole face of the elements, and thus wetability of the partition walls 11a, 11b, 11c, and 11d and the surface in pixels can be made uniform. Accordingly, a thickness of the light emitting medium layer such as the light emitting layers 14R, 14G, and 14B formed right thereon can be made uniform.

FIG. 5 is a cross-sectional view illustrating a structure of an organic EL display 100c according to another modified example of the embodiment of the present invention. In FIG. 5, the same reference numerals and signs are given to parts having the same structure as FIG. 3, and the description thereof is not repeated.

The organic EL display 100c shown in FIG. 5 is different from the organic EL display 100a shown in FIG. 3 in that the partition walls 11a, 11b, 11c, and 11d are not formed on the substrate 10, and the hole transport layer 13e is also formed on areas on the substrate 10 on which the anodes 11a, 11b, and 11c are not formed.

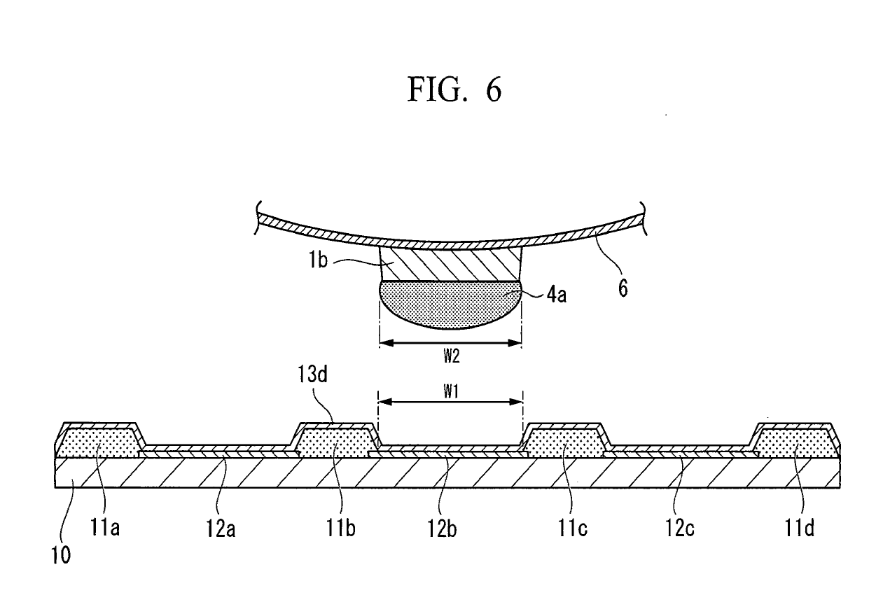

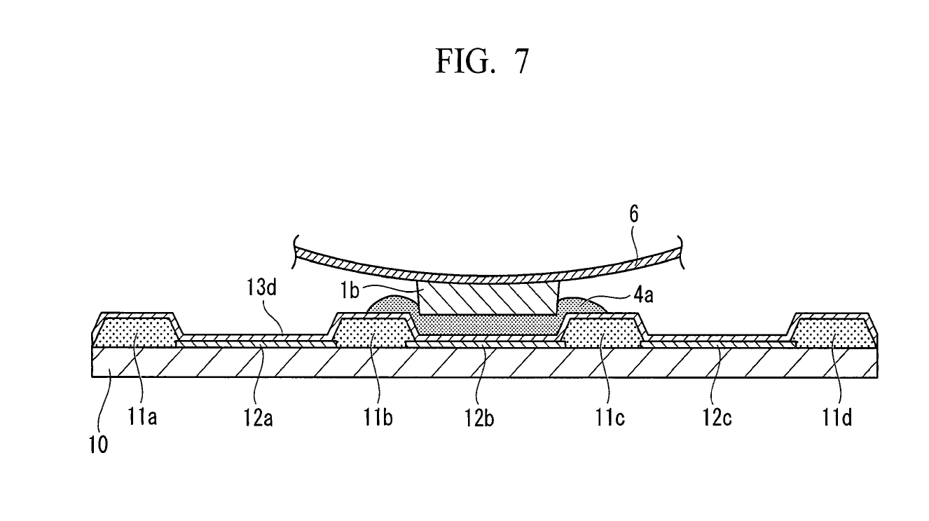

FIG. 6 and FIG. 7 are views illustrating a method of producing the organic EL display 100b (FIG. 4) according to the modified example of the embodiment of the present invention. Specifically, FIG. 6 and FIG. 7 show a process of forming the light emitting layer 14R on the hole transport layer 13d between the partition wall 11b and the partition wall 11c. The light emitting layers 14G and 14B as well as the light emitting layer 14R can be formed by the same method as the method described in FIG. 6 and FIG. 7.

The light emitting layers 14R, 14B, and 14B of the organic EL display 100a (FIG. 3) or the organic EL display 100c (FIG. 5) can be formed by the same method as the method described in FIG. 6 and FIG. 7.

FIG. 6 shows a partial enlarged view of FIG. 2, and the printing target 7 shown in FIG. 2 corresponds to the substrate 10, the partition walls 11a, 11b, 11c, and 11d, the anodes 12a, 12b, and 12c, and the hole transport layer 13d shown in FIG. 6. The ink 4a is adhered to the surface of the convex portion forming material layer 1b provided on the cylindrical block body 6 by the anilox roll 5. In the embodiment, a width W2 of the convex portion forming material layer 1b is smaller than a distance W1 between the partition walls.

When the block body 6 rotates so that the convex portion forming material layer 1b is up to the position between the partition wall 11b and the partition wall 11c, the printing target fixing platen 8 (not shown in FIG. 6 and FIG. 7) allows the substrate 10 or the like to come into contact with the ink 4a, and thus the ink 4a comes into contact with the upside of the hole transport layer 13d on the partition walls 11b and 11c, and the anode 12b, thereby performing patterning (see FIG. 7).

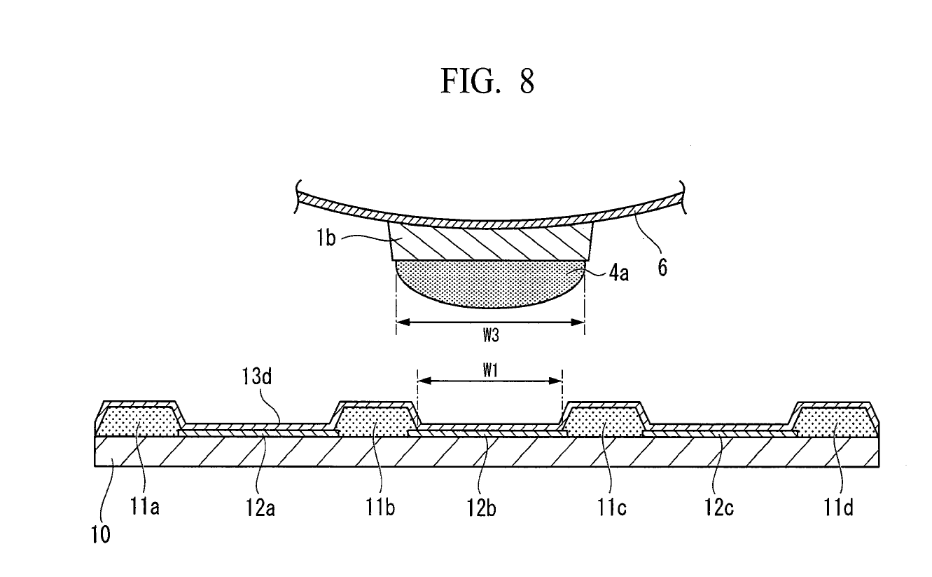

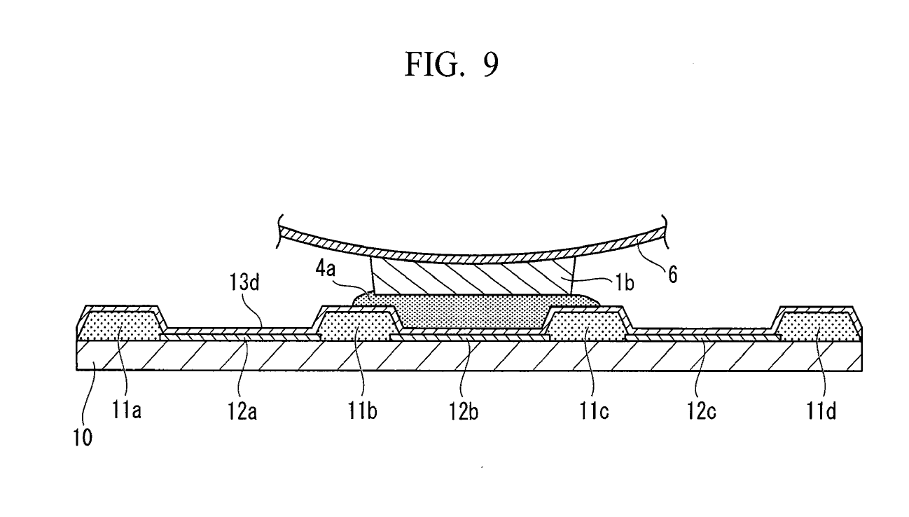

The ink 4a may be applied using the device shown in FIG. 8 and FIG. 9 other than the device shown in FIG. 6 and FIG. 7.

FIG. 8 and FIG. 9 are views illustrating another example of a method of producing the organic EL display 100b (FIG. 4) according to the modified example of the embodiment of the present invention. FIG. 8 and FIG. 9 also show a process of forming the light emitting layer 14R on the hole transport layer 13d between the partition wall 11b and the partition wall 11c in the same manner as FIG. 6 and FIG. 7.

In FIG. 8 and FIG. 9, the same reference numerals and signs are given to parts having the same structure as FIG. 6 and FIG. 7, and the description thereof is not repeated.

FIG. 8 and FIG. 9 are different from FIG. 6 and FIG. 7 in that a width W3 of the convex portion forming material layer 1b is larger that the distance W1 between the partition walls.

As the width W3 of the convex portion forming material layer 1b gets larger, it is difficult to apply the ink 4a to the space between the partition walls. However, when using the production method according to the embodiment, the ink 4a does not flow in between the partition walls 11b and 11c even when the ink 4a goes up on the partition walls 11b and 11c or even when the ink 4a flows into the adjacent organic EL element (herein, area between the partition walls 11a and 11b, or area between the partition walls 11c and 11d), and even when the position of the convex portion forming material layer 1b and the substrate 10 slightly deviates, it is possible to prevent a mixed color from occurring between adjacent pixels since the ink with a long light emitting wavelength is applied onto the ink with a short light emitting wavelength.

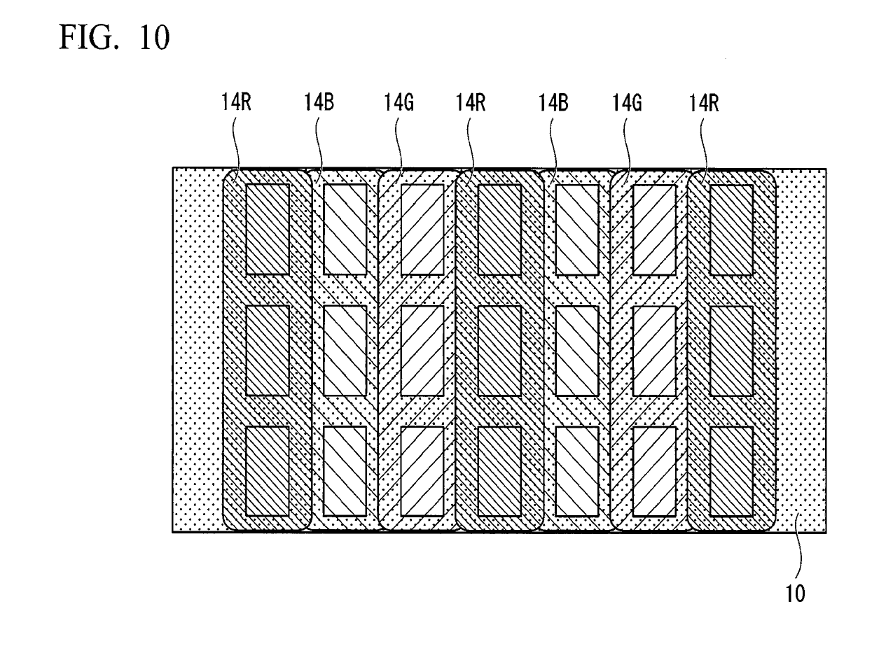

FIG. 10 is a plan view illustrating a structure of the organic EL display 100a (FIG. 3) according to the embodiment of the present invention. FIG. 10 shows a step, in which the cathode 15, the sealing resin 16, and the sealing substrate 17 are not formed, as a step of forming the partition walls 11a, 11b, 11c, 11d, . . . , the anodes 12a, 12b, 12c, . . . , the hole transport layer 13a, 13b, 13c, . . . , and the light emitting layer 14R, 14G, and 14B on the substrate 10.

FIG. 10 shows a case where total 21 (=3 lines×7 rows) organic EL elements are formed on the substrate 10 of the organic EL display 100a.

The light emitting layer 14R is applied to the organic EL elements in the first row, the fourth row, and the seventh row, the light emitting layer 14B is applied to the organic EL elements in the second row and the fifth row, and the light emitting layer 14G is applied to the organic EL elements in the third row and the sixth row.

In FIG. 10, two light emitting layers overlap in a boundary area of each row. Specifically, the light emitting layer 14G is overlapped on the light emitting layer 14B in the boundary area of the second row and the third row. The light emitting layer 14R is overlapped on the light emitting layer 14G in the boundary area of the third row and the fourth row. The light emitting layer 14R is overlapped on the light emitting layer 14B in the boundary area of the first row and the second row.

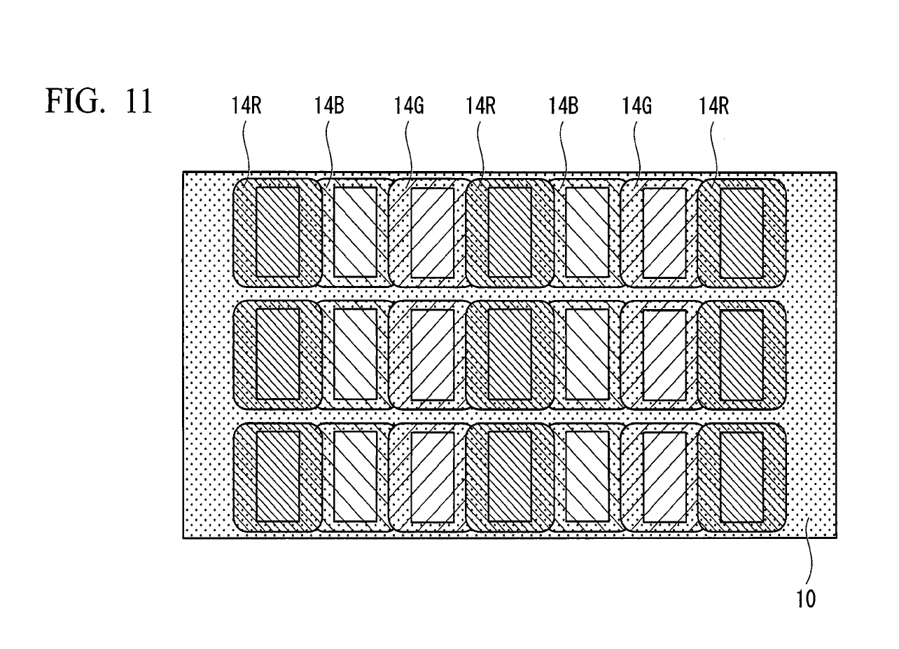

In FIG. 10, the case of applying ink forming each light emitting layer for each row has been described, but is not limited thereto. For example, ink forming each light emitting layer may be applied in the same manner as FIG. 11.

FIG. 11 is a plan view illustrating another example of the structure of the organic EL display 100a (FIG. 3) according to the embodiment of the present invention. In FIG. 11, each light emitting layer is not formed for each row of the organic EL elements as shown in FIG. 10, but each light emitting layer is formed for each element of the organic EL elements.

In FIG. 11, two light emitting layers overlap with each other in the boundary area of the organic EL elements. Specifically, the light emitting layer 14G is overlapped on the light emitting layer 14B in the boundary area of the organic EL elements in the second row and the third row. The light emitting layer 14R is overlapped on the light emitting layer 14G in the boundary area of the organic EL elements in the third row and the fourth row. The light emitting layer 14R is overlapped on the light emitting layer 14B in the boundary area of the organic EL elements in the first row and the second row.

When the light emitting layers are formed in order of length of light emitting wavelength (in order of the light emitting layers 14R, 14G, and 14B), for example, when ink of the light emitting layer 14B is applied, ink of the previously applied light emitting layer 14R or light emitting layer 14G is dissolved into the ink of the light emitting layer 14B. In this case, when voltage is applied between the anodes 12a, 12b, and 12c, and the cathode 15, the pigment of the light emitting layer 14R or the light emitting layer 14G flowing into the light emitting layer 14B emits light in spite of the area where the light emitting layer 14B is formed, and thus there is a problem that a mixed color occurs.

However, in the embodiment, the light emitting layers are formed in order of the light emitting layers 14B, 14G and 14R. Accordingly, for example, even when the ink of the previously applied light emitting layer 14B or light emitting layer 14G is dissolved into the ink of the light emitting layer 14R, the pigment of the flowing-in light emitting layer 14B or light emitting layer 14G has high light emitting energy and thus does not emit light, and the pigment of the light emitting layer 14R having low light emitting energy preferentially emits light. Accordingly, it is possible to prevent a mixed color from occurring, and thus it is possible to improve yield at the time of producing the organic EL display.

According to the embodiment, the light emitting layers 14R, 14G, and 14B are applied onto the partition walls as well as to the area interposed between the partition walls. Therefore, even when the position of applying the ink 4a of the light emitting layer slightly deviates, the ink 4a is applied to the whole face of the area interposed between the partition walls and thus it is possible to have spare precision in positioning of the block body 6 (FIG. 2) and the substrate 10 that is the printing target 7 (FIG. 2).

Even when the ink 4a of the light emitting layer overflows from the area interposed between the partition walls and flows into the ink 4a of the light emitting layer of the adjacent element, an influence on the light emitting color is small as described above and it is possible to adjust the thickness of the ink of the light emitting layer applied to the area interposed between the partition walls to be uniform.

In the embodiment, the case of the positive taper shape in which the cross sections of the partition walls 11a, 11b, 11c, and 11d are the trapezoid shape has been described. Since the partition walls 11a, 11b, 11c, and 11d are formed in such a shape, the light emitting layers are not discontinuously formed but continuously formed when the light emitting layers 14R, 14G, and 14B are formed on the partition walls 11a, 11b, 11c, and 11d.

The cross sections of the partition walls 11a, 11b, 11c, and 11d according to the embodiment may be formed in a reverse taper shape. By forming them in such a shape, ink discontinues easily at the end portions on the partition walls 11a, 11b, 11c, and 11d when the light emitting layers 14R, 14G, and 14B are formed on the partition walls 11a, 11b, 11c, and 11d. Accordingly, it is possible to prevent a mixed color from occurring by suppressing the inflow of the ink.

Heights of the partition walls 11a, 11b, 11c, and 11d according to the embodiment are preferably 0.1 μm to 5 μm, and more preferably 0.5 μm to 2 μm. The reason is because the ink invades the adjacent pixel and thus a mixed color may occur when the partition walls 11a, 11b, 11c, and 11d are too low, and disconnection may occur at the time of forming the cathode 15 when the partition walls 11a, 11b, 11c, and 11d are too high.

The light emitting layers 14R, 14G, and 14B according to the embodiment may be formed using a convex board printing method (flexography method), a concave board offset printing method, a convex board reverse offset printing method, an inkjet printing method, a concave board printing method, or the like. When using such a method, it is possible to apply the light emitting layers 14R, 14G and 14B onto the whole face of the organic EL elements using the same light emitting material. Accordingly, it is possible to simplify the process of forming the light emitting layers 14R, 14G, and 14B, and thus it is possible to improve productivity. Before forming the light emitting layers 14R, 14G, and 14B, the substrate 10 may be subjected to a surface process such as a UV (ultraviolet) process and a plasma process. Since the wetability of the surface on the partition walls 11a, 11b, 11c, and 11d and in the pixels can be made uniform, the thickness of the light emitting layers 14R, 14G, and 14B can be made uniform.

In the embodiment, the passive-matrix organic EL display has been described, but the invention is not limited thereto and may be applied to an active-matrix organic EL display.

In the embodiment, the case where the light emitting layers are formed of three colors of red, green and blue has been described, but the invention is not limited thereto. For example, the light emitting layers may be formed of four colors of red, green, blue, and yellow. In this case, the order of printing of the light emitting layers onto the substrate 10 is in order of blue, green, yellow, and red.

### EXAMPLE

Hereinafter, the invention will be additionally described by Examples and Comparative Examples, but the invention is not limited to the following examples below.

### Example 1

(Preparation of Coating Ink for Forming Organic Light Emitting Medium Layer)

A high molecular fluorescent element (or high molecular resin for coupling with the high molecular fluorescent element) was dissolved in a solvent so that the concentration of coating ink was 2.0 weight %, and thus coating ink for forming an organic light emitting medium layer was prepared.

In the high molecular fluorescent element, three colors of RGB formed of polyfluorene derivatives were used as light emitting materials. In the ink preparation composition, xylene (boiling point 139° C.) was 88 weight % and tetralin (boiling point 202° C.) was 10 weight %.

(Production of Printing Target Substrate)

A base material (Geomatec Co., Ltd.) for producing a transparent electrode in which an ITO film with surface resistivity of 15Ω is formed in a circuit pattern shape was prepared on a glass substrate with 150 mm square and 0.4 mm thick.

As for partition walls, after a positive resist ZWD6216-6 produced by ZEON CORPORATION, JAPAN was formed on a substrate face on which an ITO pattern was formed in a spin coater, partition walls having a positive taper shape were formed by photolithography, and an ITO film pattern on the substrate was partitioned. The partition walls were formed so that a partition wall width was about 15 μm in a printing direction at the time of forming a pattern to be described later, and a distance W1 between the partition walls was 32 μm.

Then, as a hole transport layer, a film was formed with a thickness of 100 nm in a spin coater using poly(3,4)ethylenedioxythiophene/polystyrene sulfonic acid (PEDOT/PSS). The formed PEDOT/PSS thin film was dried under decompression at 180° C. for 1 hour, and thus a printing target 7 (printing board) was produced.

(Production of Convex Board for Printing)

A photosensitive water-soluble polymer (water-soluble resin) as a convex portion 1b was heated at 150° C. and dissolved and it was formed to be a thickness of 0.1 μm by a spin coat method, and a forming layer of the convex portion 1b was laminated and formed on a polyethylene terephthalate (PET) base material with 0.3 mm as a base material 1a.

(Pattern Forming of Convex Board for Printing)

A convex portion and a concave portion were formed in a stripe pattern of L/S=30/111 μM (corresponding to 180 ppi) by photolithography. Red, green, and blue were printed once by once using the pattern while delaying a printing position and thus a full-color panel of three colors of RGB can be produced.

(Printing of Coating Ink for Forming Organic Light Emitting Medium Layer by Convex Printing Board S)

First, the convex printing board S according to the embodiment as shown in FIG. 1 was provided and fixed onto the block body 6 of a circular-pressing convex board printing machine (see FIG. 2) based on a convex board printing method, and the printing target 7 (printing board) was placed and fixed onto the printing target fixing platen 8.

The anilox roll 5 with the number of lines of 500 line/inch and the block body 6 were rotated to feed coating ink 4a for forming an organic light emitting medium layer to a circumferential face of the anilox roll 5 (ink feed roller) with a uniform film, and the ink 4a was fed to the top face of the convex portion of the convex printing board through the anilox roll 5. Then, the ITO film pattern forming face of the printing target 7 (printing substrate) was matched with the ITO film pattern, the printing of the pattern-shaped coating ink 4a was performed by the top face. The first printing is the patterning using the coating ink including a blue light emitting pigment.

Subsequently, in the same manner, the printing was performed in order of the coating ink including a green light emitting pigment and the coating ink including a red light emitting pigment. The band gap of the red light emitting pigment is 2.01 eV, the band gap of the green light emitting pigment is 2.38 eV, and the band gap of the blue light emitting pigment is 2.72 eV. As described above, the larger the band gap is, the shorter the light emitting wavelength is.

The coating ink 4a of the printing target 7 (printing board) after the printing was dried under the conditions of 150° C. and 5 hours, then barium of 7 nm and aluminum of 150 nm were laminated and formed from the organic light emitting medium layer formed by the coating ink 4a, and an organic EL display was produced.

### Example 2

As the hole transport layer, a film was subjected to patterning and formed using molybdenum oxides by a vacuum deposition method and a shadow mask method to be a thickness of 50 nm, instead of PEDOT/PSS. In the pattern area, a film was formed using a metal mask having an opening of 120 mm×100 mm so that a film was formed on the whole face of the display area. Except that, the organic EL display was produced by the same process as Example 1.

### Comparative Example 1

In Example 1, the first printing was patterning using the coating ink including a red light emitting pigment, and subsequently, the printing was performed in order of the coating ink including a green light emitting pigment and a blue light emitting pigment in the same manner. Except that, the organic EL display was produced by the same process as Example 1.

### Example 3

A partition wall width in the printing direction was about 22 μm and a distance W1 between partition walls was 25 μm. In the patterning of the organic light emitting medium layer using the coating ink, an opening portion of pixels was covered at the convex portion by matching the position, and the printing of the pattern-shaped coating ink formed by the top face was performed. Except that, the organic EL display was produced by the same process as Example 1.

### Example 4

In the same manner as Example 3, a partition wall width in the printing direction was about 22 μm and a distance W1 between the partition walls was 25 μm. In the convex printing board, a convex portion and a concave portion were formed in a stripe pattern of L/S=20/121 μm by photolithography. Except that, the organic EL display was produced by the same process as Example 1.

<Comparison Result>

FIG. 12 is a light emitting photograph of the organic EL display produced according to Examples 1 and 2 of the present invention. That is, FIG. 12 shows a case where the light emitting layers were formed in order of the light emitting layer 14B, the light emitting layer 14G, and the light emitting layer 14R.

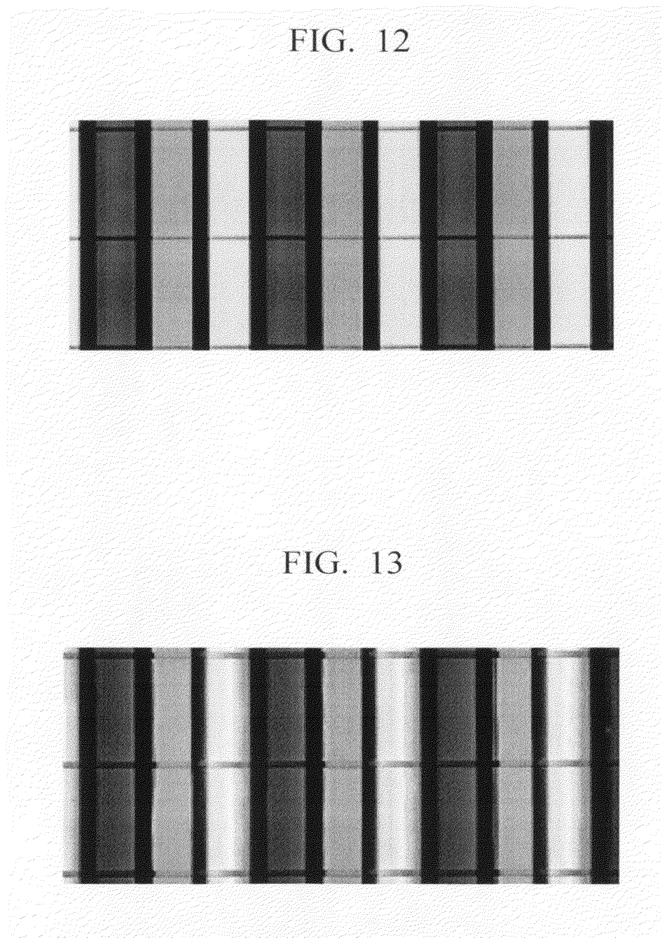

FIG. 13 is a light emitting photograph of the organic EL display produced according to Comparative Example 1. That is, FIG. 13 shows a case the light emitting layers were formed in order of the light emitting layer 14R, the light emitting layer 14G, and the light emitting layer 14B.

In the organic EL display produced according to Example 1 or 2, immediately after voltage was applied through the ITO film and a light emitting state was confirmed, the thickness of the organic light emitting medium layer was uniform and difference in light emission could not be seen as shown in FIG. 12. However, in the organic EL display produced according to Comparative Example 1, immediately after voltage was applied through the ITO film and a light emitting state was confirmed, as shown in FIG. 13, light emitting colors were sporadically different in the light emitting panel, and thus the general view was spotted non-uniformity and a mixed color occurred.

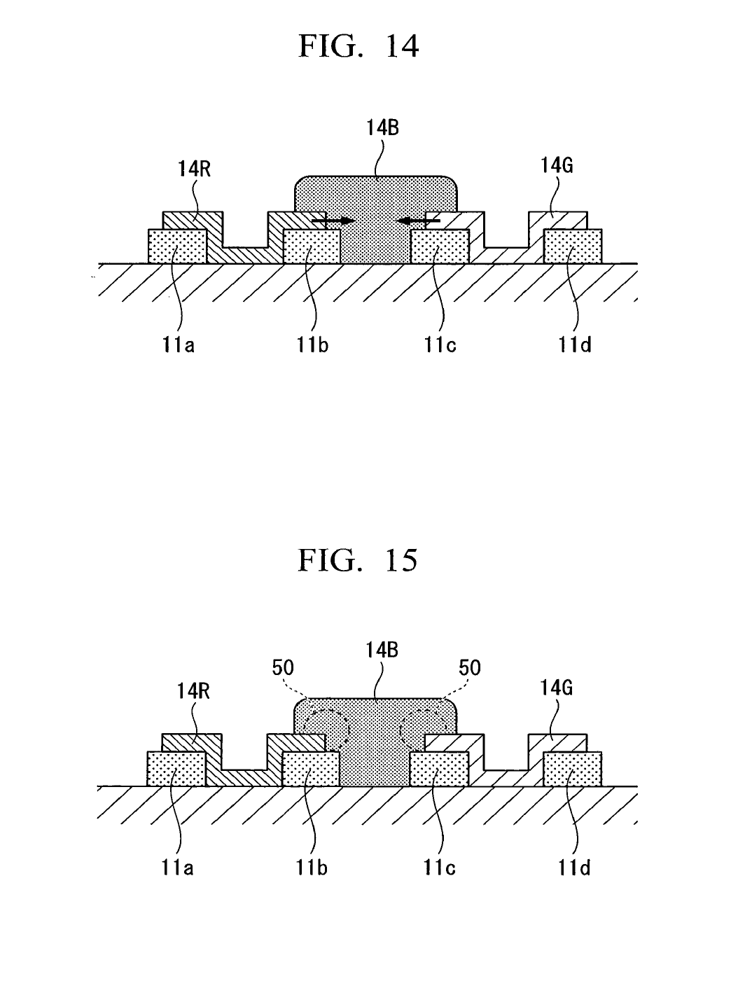

FIG. 14 and FIG. 15 are views illustrating a cause of generating a mixed color in the organic EL display produced according to Comparative Example 1. In the organic EL display produced according to Comparative Example 1, as shown in FIG. 14, the cause of generating the mixed color is that the newly coated coating ink (herein, the light emitting layer 14B) dissolved the ink (herein, the light emitting layers 14R and 14G) coated and solidified before that and drew it into pixels, and the light emitting color was changed to be non-uniformity in light emission with respect to a part 50 (see FIG. 15) where the mixing of the light emitting pigment of the adjacent pixel.

Also in Examples 3 and 4, the mixed color of the light emitting color could not be seen. In Example 3, a part overlapped with each other occurred on all of partition walls interposed between the pixels, and the light emitting layers covered the whole face of the elements. Meanwhile, in the Example 4, a part overlapped with each other and a non-overlapped part occurred. In Example 3, non-uniformity of the thickness of the film was small and the light emitting state was uniform, as compared with Example 4.

### INDUSTRIAL APPLICABILITY

The organic electroluminescence display and the production method thereof can reduce differences in chromaticity caused by a mixed color of ink to the minimum and improve production yield, and thus are effective in the production of a high-precision display.

1. An organic electroluminescence display comprising:
a substrate;
a first electrode layer that is formed on the substrate;
a first light emitting layer that is formed on the first electrode layer and emits light with a first wavelength;
a second light emitting layer that is formed to overlap at least a part thereof with the first light emitting layer and emits light with a second wavelength longer than the first wavelength; and
a second electrode layer that is formed on the first or second light emitting layer.

2. The organic electroluminescence display according to claim 1, further comprising a partition wall formed between adjacent organic electroluminescence elements on the substrate,
wherein the second light emitting layer overlaps with the first light emitting layer on the partition wall.

3. The organic electroluminescence display according to claim 2, wherein the first light emitting layer is formed on all of the faces of the first electrode and the partition wall.

4. The organic electroluminescence display according to claim 2, further comprising a hole transport layer between the first electrode layer and the second electrode layer,
wherein the hole transport layer is formed on all of the faces of the first electrode and the partition wall.

5. A method of producing an organic electroluminescence display, the method comprising:
a first process of forming a first electrode layer on a substrate;
a second process of forming a first light emitting layer that emits light with a first wavelength on the first electrode layer;
a third process of forming a second light emitting layer that emits light with a second wavelength longer than the first wavelength to overlap at least a part thereof with the first light emitting layer; and
a fourth process of forming a second electrode layer on the first or second light emitting layer.

6. The method of producing the organic electroluminescence display according to claim 5, wherein in the second process the first light emitting layer is formed by patterning ink including a first pigment emitting light with the first wavelength, and
wherein in the third process the second light emitting layer is formed by patterning ink including a second pigment emitting light with the second wavelength after the first light emitting layer is solidified.

7. The method of producing the organic electroluminescence display according to claim 6, wherein the first or second light emitting layer is formed by a convex board printing method.

8. The method of producing the organic electroluminescence display according to claim 5, further comprising a process of forming a partition wall for partitioning adjacent organic electroluminescence elements from each other,
wherein in the second process the first light emitting layer is formed on the first electrode layer and the partition wall.
